(19) United States
(12) Patent Application Publication
(10) Pub. No.: US 2026/0094632 A1
(43) Pub. Date: Apr. 2, 2026

(54) CLOCK STABILIZATION CIRCUIT, SYSTEM, AND OPERATING METHOD OF SYSTEM

(71) Applicant: SK hynix Inc., Gyeonggi-do (KR)

(72) Inventor: Jae Hoon JUNG, Gyeonggi-do (KR)

(21) Appl. No.: 19/046,522

(22) Filed: Feb. 6, 2025

(30) Foreign Application Priority Data
Oct. 2, 2024 (KR) 10-2024-0134089

(51) Int. Cl. G11C 7/10

(52) U.S. Cl. CPC G11C 7/1066; G11C 7/1009; G11C 7/1036

(57) ABSTRACT

A clock stabilization circuit includes a shift register configured to output one or more shifting signals by shifting data and an inversion flag based on a clock signal, a comparison circuit configured to output one or more comparison signals by comparing the one or more shifting signals with one or more keys, respectively, a stable flag register configured to enable a stable flag based on a first-delayed clock signal and the one or more comparison signals, the first-delayed clock signal generated by delaying the clock signal, and a mask circuit configured to output an internal clock signal by masking a second-delayed clock signal based on the stable flag, the second-delayed clock signal generated by delaying the first-delayed clock signal.

### CROSS-REFERENCES TO RELATED APPLICATION

The present application claims priority under 35 U.S.C. § 119(a) to Korean Patent Application No. 10-2024-0134089, filed on Oct. 2, 2024, which is incorporated herein by reference in its entirety.

### BACKGROUND

### 1. Technical Field

Various embodiments of the present disclosure relate to a semiconductor circuit which processes a clock signal.

### 2. Related Art

A memory device is an important component for storing data in a computer or electronic equipment, and may operate based on a clock signal. The data are transmitted to the memory device in synchronization with the clock signal. The memory device may process the data based on timing of the clock signal.

The clock signal may be unstably transmitted due to various external factors and the characteristics of a circuit itself. For example, a change of power supply or a temperature change may cause a change in the clock signal. Furthermore, in an initial interval of transmission before the clock signal is stabilized, the clock signal may be unstable. The unstable clock signal enables the memory device to erroneously process the data, and thus may cause a data loss or a system error. Accordingly, in order to maximize system performance and maintain data integrity, data need to be processed based on a clock signal in a steady state.

### SUMMARY

In an embodiment of the present disclosure, a clock stabilization circuit may include a shift register configured to output one or more shifting signals by shifting data and an inversion flag based on a clock signal, a comparison circuit configured to output one or more comparison signals by comparing the one or more shifting signals with one or more keys, respectively, a stable flag register configured to enable a stable flag based on a first-delayed clock signal and the one or more comparison signals, the first-delayed clock signal generated by delaying the clock signal, and a mask circuit configured to output an internal clock signal by masking a second-delayed clock signal based on the stable flag, the second-delayed clock signal generated by delaying the first-delayed clock signal.

In an embodiment of the present disclosure, a system may include a first device configured to output data and an inversion flag, which are synchronized with a clock signal, and a second device configured to identify one or more initial patterns in a combination of the data and the inversion flag and generate an internal clock signal based on second clock cycles after first clock cycles synchronized with the one or more initial patterns in the clock signal.

In an embodiment of the present disclosure, an operating method of a system may include outputting, by a first device, data and an inversion flag, which are synchronized with a clock signal, identifying, by a second device, one or more initial patterns in a combination of the data and the inversion flag, and generating, by the second device, an internal clock signal based on second clock cycles after first clock cycles synchronized with the one or more initial patterns in the clock signal.

### BRIEF DESCRIPTION OF THE DRAWINGS

FIG. 1 is a diagram illustrating a clock signal that is transmitted between devices in a system according to an embodiment of the present disclosure.

FIG. 2 is a block diagram illustrating a system according to an embodiment of the present disclosure.

FIG. 3 is a diagram for describing a DBI function of the system according to an embodiment of the present disclosure.

FIG. 4 is a diagram illustrating initial patterns according to an embodiment of the present disclosure.

FIG. 5 is a block diagram illustrating a clock stabilization circuit according to an embodiment of the present disclosure.

FIG. 6 is a timing diagram for describing an operation of the system including the clock stabilization circuit of FIG. 5 according to an embodiment of the present disclosure.

FIG. 7 is a flowchart illustrating an operating method of the system according to an embodiment of the present disclosure.

FIG. 8 is a block diagram illustrating a memory system according to an embodiment of the present disclosure.

### DETAILED DESCRIPTION

Hereinafter, embodiments of the present disclosure will be described in detail with reference to the accompanying drawings.

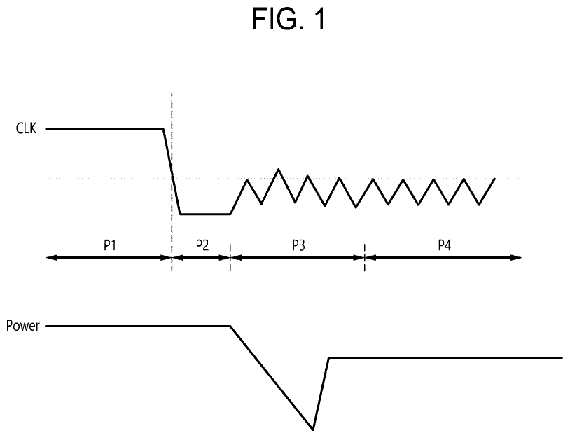

FIG. 1 is a diagram illustrating a clock signal CLK that is transmitted between devices in a system (e.g., a memory device and a controller in a memory system) according to an embodiment of the present disclosure.

Referring to FIG. 1, the clock signal CLK may be transmitted sequentially through intervals P1 to P4. In the illustrated embodiment of FIG. 1, the clock signal CLK may be at a high level without toggling in the interval P1. In another embodiment, the clock signal CLK may be at a predetermined voltage level not the high level in the interval P1. The interval P1 may be an interval in which the clock signal CLK is in a deactivation state. That is, the clock signal CLK does not continue to continuously toggle, but may be in the deactivation state when the transmission of data is not present or in a low power mode of the system.

The clock signal CLK may transition from a high level to a low level in the interval P2, and may be transmitted at a low level. In another embodiment, the clock signal CLK may be at a predetermined voltage level not a low level in the interval P2. The interval P2 may be an interval in which the clock signal CLK is transmitted as a preamble.

The clock signal CLK may toggle in the interval P3. Power within a memory device may experience a sudden drop due to the start of the toggling of the clock signal CLK in the interval P3. The sudden drop of the power may make the clock signal CLK unstable. The interval P3 may be an interval in which the clock signal CLK is transmitted in an unsteady state or a transient state.

After the supply of power is stabilized, the clock signal CLK may be transmitted in a steady state in the interval P4.

The clock signal CLK in the deactivation state in the interval P1 may be transmitted as illustrated in FIG. 1 when the transmission of burst data is started in a system, for example. A transmission device of the system might not transmit data in the interval P3 because the clock signal CLK in the interval P3 may be unstable, and may transmit data based on the clock signal CLK in the steady state in the interval P4. A reception device of the system may count the clock cycles of the clock signal CLK in order to disregard the clock signal CLK of the interval P3, and may identify the start point of the interval P4. How many clock cycles of the clock signal CLK will be disregarded may be predetermined between the transmission device and the reception device. However, the counting of the clock signal CLK may be inaccurate in a situation in which the unit interval (UI) of a signal is developed to be gradually decreased.

As such, the counting of the clock signal CLK may be inaccurate. Accordingly, a scheme that removes or reduces the interval P3 by improving power droop and recovery characteristics may be considered. However, it may be difficult to maintain consistent performance during an operation of a system because an analog characteristic is associated with the scheme.

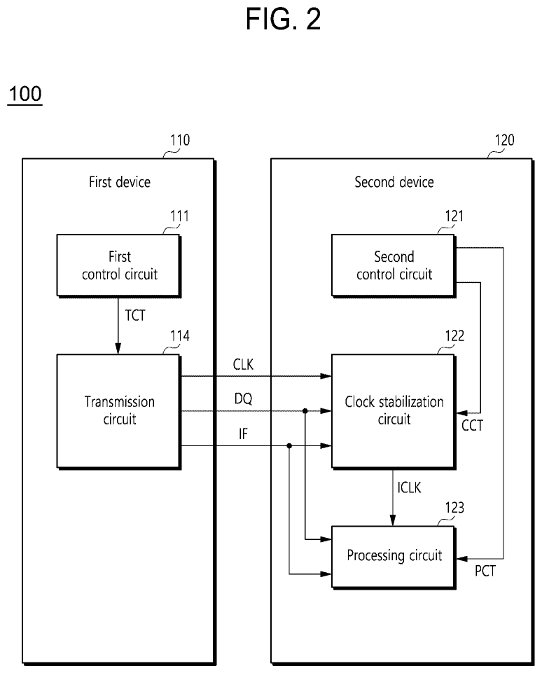

FIG. 2 is a block diagram illustrating a system 100 according to an embodiment of the present disclosure.

The system 100 may include a first device 110 and a second device 120. Each of the components of each of the first device 110 and the second device 120 may consist of hardware, software, firmware, or a combination thereof.

The first device 110 may include a first control circuit 111 and a transmission circuit 114.

The first control circuit 111 may control the transmission circuit 114 through a transmission control signal TCT.

The transmission circuit 114 may transmit, to the second device 120, a clock signal CLK, and data DQ and an inversion flag IF synchronized with the clock signal CLK. The data DQ and the inversion flag IF may include one or more initial patterns. The one or more initial patterns may be transmitted in the interval P3 of FIG. 1. Clock cycles of the clock signal CLK, which have been synchronized with the one or more initial patterns, may be in an unsteady state. The one or more initial patterns may be used to identify the start point of the clock cycles in the steady state in the clock signal CLK.

Each of the one or more initial patterns may consist of the data DQ and the inversion flag IF. At least one initial pattern of the one or more initial patterns may include the data DQ including “1s” of the majority and the inversion flag IF in an enable state, for example, “1”.

According to an embodiment, the transmission circuit 114 may transmit, to the second device 120, a predetermined number of clock cycles as the clock signal CLK in a pre-running interval before transmitting the one or more initial patterns.

According to an embodiment, the first control circuit 111 may control the second device 120 to store one or more keys in a clock stabilization circuit 122 before transmitting, to the second device 120, the data DQ and the inversion flag IF including the one or more initial patterns. The one or more keys may be the same as the one or more initial patterns, respectively. For example, the first control circuit 111 may control the second device 120 to store the one or more keys in the clock stabilization circuit 122 during the booting of the system 100. The first control circuit 111 may control the second device 120 to change the stored one or more keys.

The second device 120 may include a second control circuit 121, the clock stabilization circuit 122, and a processing circuit 123.

The second control circuit 121 may control the clock stabilization circuit 122 through a clock stabilization control signal CCT and control the processing circuit 123 through a processing control signal PCT.

The clock stabilization circuit 122 may receive the data DQ and inversion flag IF synchronized with the clock signal CLK. The clock stabilization circuit 122 may identify the one or more initial patterns in a combination of the data DQ and the inversion flag IF. The clock stabilization circuit 122 may generate an internal clock signal ICLK, based on second clock cycles after first clock cycles synchronized with the one or more initial patterns in the clock signal CLK. The internal clock signal ICLK may be generated based on the second clock cycles in the steady state except the first clock cycles in the unsteady state in the clock signal CLK.

The clock stabilization circuit 122 may store the one or more keys identical with the one or more initial patterns. The clock stabilization circuit 122 may identify the one or more initial patterns by comparing the data DQ and the inversion flag IF with the one or more keys.

According to an embodiment, the one or more keys may be hard-wired to the clock stabilization circuit 122 in a manufacturing operation. According to an embodiment, the one or more keys stored in the clock stabilization circuit 122 may be changed under the control of the first device 110.

The processing circuit 123 may process the data DQ and the inversion flag IF based on the internal clock signal ICLK. Specifically, the processing circuit 123 may generate internal data and an internal inversion flag based on the data DQ and the inversion flag IF. Furthermore, the processing circuit 123 may capture the internal data and the internal inversion flag based on the internal clock signal ICLK. Furthermore, the processing circuit 123 may selectively invert the captured internal data based on the captured internal inversion flag. Specifically, the processing circuit 123 may invert the captured internal data when the captured internal inversion flag is in the enable state, and might not invert the captured internal data when the captured internal inversion flag is in a disable state.

According to an embodiment, the system 100 may be a memory system. The first device 110 and the second device 120 may be a controller and a memory device that are included in a memory system, or vice versa.

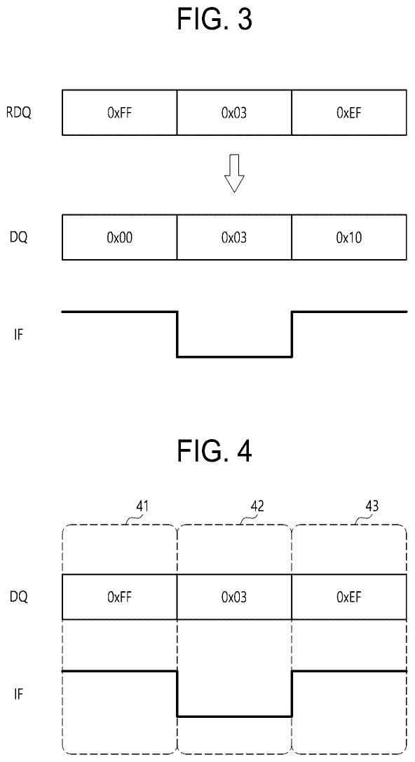

FIG. 3 is a diagram for describing a data bus inversion (DBI) function of the system 100 according to an embodiment of the present disclosure.

Referring to FIG. 3, in order to reduce power consumption, the data DQ may be transmitted from the first device 110 to the second device 120 according to a DBI method. According to the DBI method, when original data RDQ include a majority of “1s”, the first device 110 may generate the data DQ by inverting the bits of each of the original data RDQ, and may transmit, to the second device 120, the data DQ along with the inversion flag IF in the enable state. The inversion flag IF in the enable state may indicate that the data DQ transmitted along with the inversion flag IF have been inverted from the original data RDQ. The inversion flag IF in the disable state may indicate that the data DQ transmitted along with the inversion flag IF are the original data RDQ. Accordingly, as the data DQ that are transmitted along with the inversion flag IF in the enable state are inverted again, the original data RDQ may be restored. The inversion flag IF may be enabled as “1” and may be disabled as “0”, for example.

For example, the original data RDQ may be “0xFF, 0x03, and 0xEF”. The data DQ that are transmitted from the first device 110 to the second device 120 may be “0x00, 0x03, and 0x10”. Specifically, the original data RDQ “0xFF” may be inverted into the data DQ “0x00” because the original data RDQ “0xFF” include a majority of “1s”. The data DQ “0x00” may be transmitted along with the inversion flag IF “1”. The data DQ “0x00” may be inverted again based on the inversion flag IF “1”. Accordingly, the original data RDQ “0xFF” may be restored. The original data RDQ “0x03” may be transmitted as the data DQ “0x03” along with the inversion flag IF “0”. The data DQ “0x03” may be processed without any change, i.e., without a restoration process based on the inversion flag IF “0”. The original data RDQ “0xEF” may be inverted into the data DQ “0x10” because the original data RDQ “0xEF” include a majority of “1s”. The data DQ “0x10” may be transmitted along with the inversion flag IF “1”. The data DQ “0x10” may be inverted again based on the inversion flag IF “1”. Accordingly, the original data RDQ “0xEF” may be restored.

According to circumstances, all of the original data RDQ “0xFF, 0x03, and 0xEF” may be transmitted from the first device 110 to the second device 120 along with the inversion flags IF “0, 0, and 0” without being inverted. The second device 120 may process the data DQ “0xFF, 0x03, and 0xEF” without any change, i.e., without a restoration process based on the inversion flags IF “0, 0, and 0”.

FIG. 4 is a diagram illustrating initial patterns 41 to 43 according to an embodiment of the present disclosure.

Referring to FIG. 4, the initial patterns 41 to 43 may include a pattern that has not been defined in the state in which the DBI function is supported, that is, a pattern consisting of the data DQ and the inversion flag IF “1” including a majority of “1s”. Specifically, the initial patterns 41 to 43 may include the data DQ “0xFF, 0x03, and 0xEF” and the inversion flags IF “1, 0, and 1” corresponding to the data DQ. In this case, the data DQ “0xFF” and inversion flag IF “1” of the initial pattern 41 including a majority of “1s” may be a pattern that has not been defined in the state in which the DBI function is supported. Furthermore, the data DQ “0xEF” and inversion flag IF “1” of the initial pattern 43 including a majority of “1s” may also be a pattern that has not been defined in the state in which the DBI function is supported.

The patterns 41 and 43 may be used as initial patterns because the patterns have not been defined in the state in which the DBI function is supported, and may be distinguished from normal data. The data DQ “0xFF, 0x03, and 0xEF” that are transmitted as the initial patterns may be used as the normal data DQ because the data DQ “0xFF, 0x03, and 0xEF” are transmitted along with the inversion flags IF “0, 0, and 0” that comply with flags defined in the DBI function.

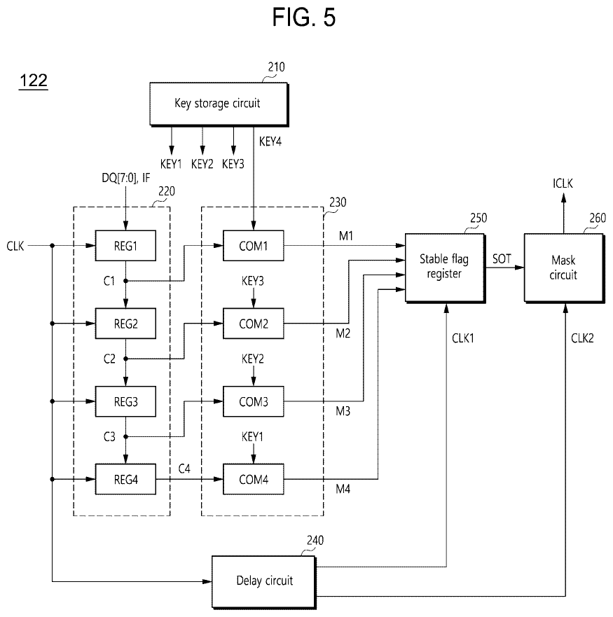

FIG. 5 is a block diagram illustrating the clock stabilization circuit 122 according to an embodiment of the present disclosure. In the embodiment of FIG. 5, four initial patterns, e.g., first to fourth initial patterns, may be transmitted through the data DQ and the inversion flag IF.

Referring to FIG. 5, the clock stabilization circuit 122 may include a key storage circuit 210, a shift register 220, a comparison circuit 230, a delay circuit 240, a stable flag register 250, and a mask circuit 260. Although not illustrated, the components included in the clock stabilization circuit 122 may operate based on the clock stabilization control signal CCT that is transmitted from the second control circuit 121, as shown in FIG. 2.

The key storage circuit 210 may store first to fourth keys KEY1 to KEY4 and output the first to fourth keys KEY1 to KEY4. The first to fourth keys KEY1 to KEY4 may be the same as first to fourth initial patterns, respectively. When each of the first to fourth initial patterns consists of the data DQ of 8 bits and the inversion flag IF of 1 bit, each of the first to fourth keys KEY1 to KEY4 may consist of 9 bits. According to an embodiment, the key storage circuit 210 may change the stored first to fourth keys KEY1 to KEY4 under the control of the first device 110.

The shift register 220 may output first to fourth shifting signals C1 to C4 by shifting the data DQ and the inversion flag IF based on the clock signal CLK. Each of the first to fourth shifting signals C1 to C4 may consist of the data DQ of 8 bits and the inversion flag IF of 1 bit.

The shift register 220 may include first to fourth registers REG1 to REG4. The first register REG1 may receive and store the data DQ and the inversion flag IF based on the clock signal CLK. The first register REG1 may output the stored data DQ and the inversion flag IF as the first shifting signal C1 based on the clock signal CLK. The second register REG2 may receive and store the data DQ and the inversion flag IF that are output by the first register REG1 as the first shifting signal C1 based on the clock signal CLK. The second register REG2 may output the stored data DQ and inversion flag IF as the second shifting signal C2 based on the clock signal CLK. The third register REG3 may receive and store the data DQ and the inversion flag IF that are output by the second register REG2 as the second shifting signal C2 based on the clock signal CLK. The third register REG3 may output the stored data DQ and inversion flag IF as the third shifting signal C3 based on the clock signal CLK. The fourth register REG4 may receive and store the data DQ and the inversion flag IF that are output by the third register REG3 as the third shifting signal C3 based on the clock signal CLK. The fourth register REG4 may output the stored data DQ and inversion flag IF as the fourth shifting signal C4 based on the clock signal CLK.

The comparison circuit 230 may output first to fourth comparison signals M1 to M4 by comparing the first to fourth shifting signals C1 to C4 and the first to fourth keys KEY1 to KEY4, respectively.

The comparison circuit 230 may include first to fourth comparators COM1 to COM4. The first to fourth comparators COM1 to COM4 may receive the first to fourth keys KEY1 to KEY4 that are output by the key storage circuit 210, may receive the first to fourth shifting signals C1 to C4 that are output by the first to fourth registers REG1 to REG4, and may output the first to fourth comparison signals M1 to M4. Each of the first to fourth comparators COM1 to COM4 may compare a corresponding shifting signal and a corresponding key, and may output a corresponding comparison signal based on a determination that the corresponding shifting signal and the corresponding key are identical with each other. For example, the first comparator COM1 may output the first comparison signal M1 in the disable state based on a determination that the first shifting signal C1 and the first key KEY1 are different from each other, and may output the first comparison signal M1 in the enable state based on a determination that the first shifting signal C1 and the first key KEY1 are identical with each other. Each of the first to fourth comparison signals M1 to M4 may be enabled as “1” and may be disabled as “0”, for example.

The delay circuit 240 may output a first-delayed clock signal CLK1 and a second-delayed clock signal CLK2 based on the clock signal CLK. Specifically, the delay circuit 240 may output the first-delayed clock signal CLK1 by delaying the clock signal CLK, and may output the second-delayed clock signal CLK2 by delaying the first-delayed clock signal CLK1.

The stable flag register 250 may receive and store the first to fourth comparison signals M1 to M4 based on the first-delayed clock signal CLK1. The stable flag register 250 may output a stable flag SOT based on the stored first to fourth comparison signals M1 to M4, based on the first-delayed clock signal CLK1. Specifically, the stable flag register 250 may output the stable flag SOT in the enable state based on the first to fourth comparison signals M1 to M4 in the enable state. The stable flag register 250 may maintain the stable flag SOT in the enable state.

The mask circuit 260 may output the internal clock signal ICLK by masking the second-delayed clock signal CLK2 based on the stable flag SOT. Specifically, while the stable flag SOT is in the disable state, the mask circuit 260 may block (mask) the second-delayed clock signal CLK2, and may output the internal clock signal ICLK at a predetermined voltage level, for example, at a low level. While the stable flag SOT is in the enable state, the mask circuit 260 may output the second-delayed clock signal CLK2 as the internal clock signal ICLK.

According to an embodiment, the number of initial patterns that are transmitted from the first device 110 might not be four. Each of the number of registers included in the shift register 220 and the number of comparators included in the comparison circuit 230 may be the same as the number of initial patterns.

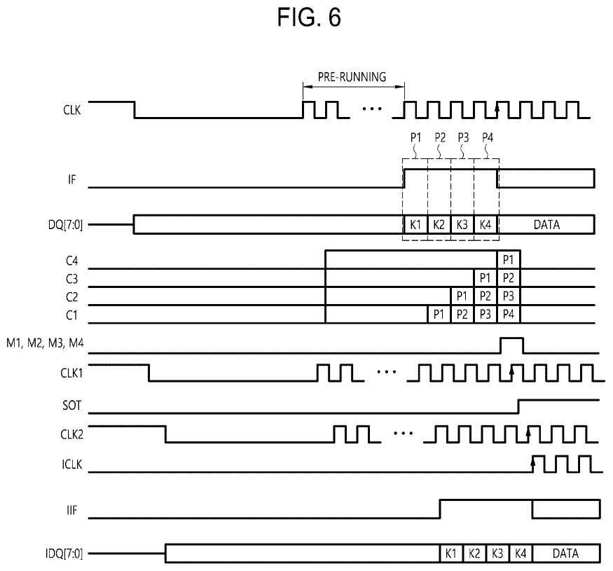

FIG. 6 is a timing diagram for describing an operation of the system 100 including the clock stabilization circuit 122 of FIG. 5 according to an embodiment of the present disclosure.

Referring to FIG. 6, the transmission circuit 114 of the first device 110 in FIG. 2 may transmit the clock signal CLK, the data DQ, and the inversion flag IF to the second device 120. The clock signal CLK may include a predetermined number of clock cycles in a pre-running interval before the first to fourth initial patterns P1 to P4 are transmitted. According to an embodiment, the pre-running interval may be omitted.

First to fourth initial patterns P1 to P4 may include the data DQ K0, K1, K2, and K3, respectively. Each of the data DQ K0, K1, K2, and K3 may include a majority of “1s”. Each of the first to fourth initial patterns P1 to P4 may include the inversion flag IF “1”. As described above, according to an embodiment, only some initial patterns not all of the first to fourth initial patterns P1 to P4 may be patterns that have not been defined in the state in which the DBI function is supported.

The second device 120 may determine the start point of clock cycles in the steady state in the clock signal CLK by identifying the first to fourth initial patterns P1 to P4 included in the data DQ and the inversion flag IF. The start point of the clock cycles in the steady state in the clock signal CLK may be the first rising edge (indicated by an arrow) after clock cycles synchronized with the first to fourth initial patterns P1 to P4. The second device 120 may receive the data DQ by using the internal clock signal ICLK based on the clock cycles in the steady state.

Specifically, the first initial pattern P1 may be sequentially transmitted from the first register REG1 to the fourth register REG4, and may be sequentially output as the first shifting signal C1 to the fourth shifting signal C3. The second to fourth initial patterns P2 to P4 may also be processed similarly to the first initial pattern P1. If the first to fourth initial patterns P1 to P4 are simultaneously output as the first to fourth shifting signals C1 to C4, respectively, the first to fourth comparators COM1 to COM4 may determine that the first to fourth initial patterns P1 to P4 are the same as the first to fourth keys KEY1 to KEY4, respectively, and may enable the first to fourth comparison signals M1 to M4, respectively. Each of the first to fourth registers REG1 to REG4 may stop a shifting operation based on each of the first to fourth comparison signals M1 to M4 in the enable state.

The stable flag register 250 may receive the first to fourth comparison signals M1 to M4 based on the first-delayed clock signal CLK1, and may maintain the stable flag SOT in the enable state based on the first to fourth comparison signals M1 to M4 in the enable state.

While the stable flag SOT is in the disable state, the mask circuit 260 may mask the second-delayed clock signal CLK2 and output the internal clock signal ICLK at a low level. While the stable flag SOT is in the enable state, the mask circuit 260 may output the second-delayed clock signal CLK2 as the internal clock signal ICLK. As a result, clock cycles from the first rising edge (indicated by an arrow) after clock cycles synchronized with the first to fourth initial patterns P1 to P4 in the clock signal CLK may be generated as the internal clock signal ICLK.

The processing circuit 123 may generate internal data IDQ and an internal inversion flag IIF by delaying the data DQ and the inversion flag IF, respectively. Furthermore, the processing circuit 123 may capture and process the internal data IDQ and the internal inversion flag IIF based on the internal clock signal ICLK. Furthermore, the processing circuit 123 may selectively invert the captured internal data based on the captured internal inversion flag. Specifically, the processing circuit 123 may invert the captured internal data when the captured internal inversion flag is in the enable state, and might not invert the captured internal data when the captured internal inversion flag is in the disable state.

The clock stabilization circuit 122 may effectively exclude clock cycles in the unsteady state from the clock signal CLK by identifying the first to fourth initial patterns P1 to P4, and may generate the internal clock signal ICLK based on clock cycles in the steady state. Performance of the system 100 can be improved because the processing circuit 123 processes the data DQ based on the internal clock signal ICLK in the steady state.

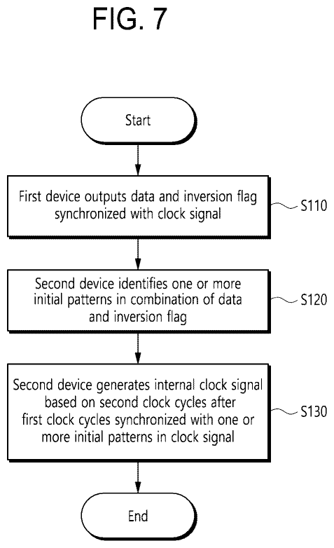

FIG. 7 is a flowchart illustrating an operating method of the system 100 according to an embodiment of the present disclosure.

Referring to FIG. 7, in operation S110, the first device 110 may output the data DQ and inversion flag IF synchronized with the clock signal CLK. According to an embodiment, the operation of outputting the data DQ and inversion flag IF synchronized with the clock signal CLK may include an operation of transmitting a predetermined number of clock cycles to the second device 120 as the clock signal CLK in a pre-running interval before the first device 110 transmits one or more initial patterns.

In operation S120, the second device 120 may identify one or more initial patterns in a combination of the data DQ and the inversion flag IF that are output by the first device 110. At least one initial pattern of the one or more initial patterns may include the data DQ including a majority of “1s” and the inversion flag IF in the enable state. According to an embodiment, the operation of identifying the one or more initial patterns may include an operation of reading, by the second device 120, one or more keys identical with the one or more initial patterns from the key storage circuit 210, an operation of comparing, by the second device 120, the data DQ and the inversion flag IF with the one or more keys, and an operation of enabling, by the second device 120, the stable flag SOT based on a determination that all of the data DQ and the inversion flag IF are the same as the one or more keys.

In operation S130, the second device 120 may generate the internal clock signal ICLK based on second clock cycles after first clock cycles synchronized with the one or more initial patterns in the clock signal CLK. According to an embodiment, the operation of generating the internal clock signal ICLK may include an operation of outputting, by the second device 120, the internal clock signal ICLK by masking clock cycles corresponding to the first clock cycles in a delayed clock signal based on the stable flag SOT.

According to an embodiment, the operating method of the system 100 may further include an operation of controlling, by the first device 110, the second device 120 to store the one or more keys in the key storage circuit 210 before the operation S110 of outputting the data DQ and the inversion flag IF.

According to an embodiment, the operating method of the system 100 may further include an operation of generating, by the second device 120, internal data and internal inversion flag based on the data DQ and the inversion flag IF, an operation of capturing, by the second device 120, the internal data and the internal inversion flag based on the internal clock signal ICLK, and an operation of selectively inverting, by the second device 120, the captured internal data based on the captured internal inversion flag.

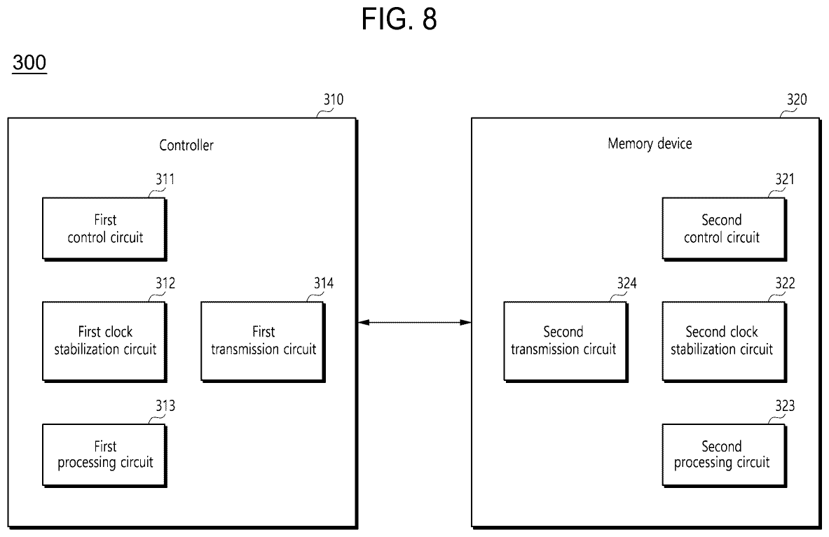

FIG. 8 is a block diagram illustrating a memory system 300 according to an embodiment of the present disclosure.

Referring to FIG. 8, the memory system 300 may store data that are received from an external device in response to a write request from the external device. Furthermore, the memory system 300 may transmit stored data to the external device in response to a read request from the external device.

The memory system 300 may include a memory device 320 and a controller 310.

The memory device 320 may store data in the memory device by performing a write operation and output, to the controller 310, data stored in the memory device by performing a read operation, under the control of the controller 310.

The memory device 320 may include a second control circuit 321, a second clock stabilization circuit 322, a second processing circuit 323, and a second transmission circuit 324. The second control circuit 321, the second clock stabilization circuit 322, and the second processing circuit 323 may be constructed and operated similarly to the second control circuit 121, the clock stabilization circuit 122, and the processing circuit 123 of FIG. 2, respectively.

The second transmission circuit 324 may be constructed and operated similarly to the transmission circuit 114 of FIG. 2. Specifically, the second transmission circuit 324 of the memory device 320 may transmit, to the controller 310, data and an inversion flag synchronized with a clock signal under the control of the second control circuit 321 similar to the operation of the transmission circuit 114 of FIG. 2.

The controller 310 may store data in the memory device 320 by controlling the memory device 320 to perform a write operation. Specifically, the controller 310 may transmit, to the memory device 320, data and an inversion flag synchronized with a clock signal. The memory device 320 may process the data and the inversion flag by generating an internal clock signal from the clock signal that is received from the controller 310.

The controller 310 may read data from the memory device 320 by controlling the memory device 320 to perform a read operation. The memory device 320 may transmit, to the controller 310, data and an inversion flag synchronized with a clock signal by performing a read operation. The controller 310 may process the data and the inversion flag by generating an internal clock signal from the clock signal that is received from the memory device 320.

The controller 310 may include a first control circuit 311, a first clock stabilization circuit 312, a first processing circuit 313, and a first transmission circuit 314. The first transmission circuit 314 may be constructed and operated similarly to the transmission circuit 114 of FIG. 2.

The first clock stabilization circuit 312 may be constructed and operated similarly to the clock stabilization circuit 122 of FIG. 2. Specifically, the first clock stabilization circuit 312 of the controller 310 may receive data and an inversion flag synchronized with a clock signal that is output by the memory device 320, may identify one or more initial patterns in a combination of the data and the inversion flag, and may generate an internal clock signal based on second clock cycles after first clock cycles synchronized with the one or more initial patterns in the clock signal, similarly to the operation of the clock stabilization circuit 122 of FIG. 2.

The first processing circuit 313 may generate internal data and an internal inversion flag based on the data and the inversion flag that are output by the memory device 320, may capture the internal data and the internal inversion flag based on the internal clock signal that is output by the first clock stabilization circuit 312, and may selectively invert the captured internal data based on the captured internal inversion flag.

The first control circuit 311 may control the first clock stabilization circuit 312, the first processing circuit 313, and the first transmission circuit 314.

The memory system 300 may include a personal computer memory card international association (PCMCIA) card, a smart media card, a memory stick, various multimedia cards (e.g., an MMC, an eMMC, an RS-MMC, and MMC-micro), secure digital (SD) cards (e.g., SD, mini-SD, and micro-SD), universal flash storage (UFS), or a solid state drive (SSD).

The memory device 320 may include a nonvolatile memory device and a volatile memory device. The nonvolatile memory device may include various types of memory, such as NAND flash memory, 3D NAND flash memory, NOR flash memory, resistive random access memory (RRAM), phase-change memory (PRAM), magnetoresistive random access memory (MRAM), ferroelectric random access memory (FRAM), or spin transfer torque random access memory (STT-RAM). The volatile memory device may include dynamic random access memory (DRAM) and static random access memory (SRAM).

The above description is merely a description of the technical spirit of the present disclosure, and those skilled in the art may change and modify the embodiments of the present disclosure in various ways without departing from the essential characteristics of the present disclosure. Accordingly, the disclosed embodiments should not be construed as limiting the technical scope of the present disclosure, but should be construed as describing the technical scope of the present disclosure. The technical scope of the present disclosure is not restricted by the embodiments. The range of protection of the embodiments should be construed based on the following claims, and all technical details within an equivalent scope of the embodiments should be construed as being included in the scope of rights of the present disclosure. Furthermore, the embodiments may be combined to form additional embodiments.

What is claimed is:

1. A clock stabilization circuit comprising:
a shift register configured to output one or more shifting signals by shifting data and an inversion flag based on a clock signal;
a comparison circuit configured to output one or more comparison signals by comparing the one or more shifting signals with one or more keys, respectively;
a stable flag register configured to enable a stable flag based on a first-delayed clock signal and the one or more comparison signals, the first-delayed clock signal generated by delaying the clock signal; and
a mask circuit configured to output an internal clock signal by masking a second-delayed clock signal based on the stable flag, the second-delayed clock signal generated by delaying the first-delayed clock signal.

2. The clock stabilization circuit of claim 1, wherein:
the comparison circuit comprises one or more comparators, and
each of the one or more comparators enables a corresponding comparison signal of the one or more comparison signals based on a determination that a corresponding shifting signal of the one or more shifting signals is the same as a corresponding key of the one or more keys.

3. The clock stabilization circuit of claim 1, further comprising a key storage circuit configured to store the one or more keys, and change the stored one or more keys under a control of an external device.

4. The clock stabilization circuit of claim 1, wherein:
the one or more keys are identical with one or more initial patterns included in a combination of the data and the inversion flag, and
at least one initial pattern of the one or more initial patterns comprises data entry comprising a majority of “1s” and a first inversion flag in an enable state, among the combination.

5. The clock stabilization circuit of claim 1, wherein the mask circuit masks the second-delayed clock signal while the stable flag is in a disable state and outputs the second-delayed clock signal as the internal clock signal while the stable flag is in an enable state.

6. A system comprising:
a first device configured to output data and an inversion flag, which are synchronized with a clock signal; and
a second device configured to identify one or more initial patterns in a combination of the data and the inversion flag and generate an internal clock signal based on second clock cycles after first clock cycles synchronized with the one or more initial patterns in the clock signal.

7. The system of claim 6, wherein at least one initial pattern of the one or more initial patterns comprises data entry comprising a majority of “1s” and a first inversion flag in an enable state, among the combination.

8. The system of claim 6, wherein the second device reads one or more keys identical with the one or more initial patterns from a key storage circuit, compares the data and the inversion flag with the one or more keys, and identifies the one or more initial patterns by enabling a stable flag based on a determination that all of the data and the inversion flag are identical with the one or more keys.

9. The system of claim 8, wherein the second device generates the internal clock signal by masking clock cycles corresponding to the first clock cycles in a delayed clock signal based on the stable flag, the delayed clock signal generated by delaying the clock signal.

10. The system of claim 8, wherein the first device controls the second device to store the one or more keys in the key storage circuit, before transmitting the data and the inversion flag to the second device.

11. The system of claim 6, wherein the first device transmits a predetermined number of clock cycles to the second device as the clock signal in a pre-running interval before transmitting the one or more initial patterns.

12. The system of claim 6, wherein the second device generates internal data and an internal inversion flag based on the data and the inversion flag, captures the internal data and the internal inversion flag based on the internal clock signal, and selectively inverts the captured internal data based on the captured internal inversion flag.

13. An operating method of a system, the operating method comprising:
outputting, by a first device, data and an inversion flag, which are synchronized with a clock signal;
identifying, by a second device, one or more initial patterns in a combination of the data and the inversion flag; and
generating, by the second device, an internal clock signal based on second clock cycles after first clock cycles synchronized with the one or more initial patterns in the clock signal.

14. The operating method of claim 13, wherein at least one initial pattern of the one or more initial patterns comprises data entry comprising a majority of “1s” and a first inversion flag in an enable state, among the combination.

15. The operating method of claim 13, wherein identifying the one or more initial patterns comprises:
reading, by the second device, one or more keys identical with the one or more initial patterns from a key storage circuit;
comparing, by the second device, the data and the inversion flag with the one or more keys; and
enabling, by the second device, a stable flag based on a determination that all of the data and the inversion flag are identical with the one or more keys.

16. The operating method of claim 15, wherein generating the internal clock signal comprises generating, by the second device, the internal clock signal by masking clock cycles corresponding to the first clock cycles in a delayed clock signal based on the stable flag, the delayed clock signal generated by delaying the clock signal.

17. The operating method of claim 15, further comprising controlling, by the first device, the second device to store the one or more keys in the key storage circuit before outputting the data and the inversion flag.

18. The operating method of claim 13, wherein outputting the data and the inversion flag comprises transmitting, by the first device, a predetermined number of clock cycles to the second device as the clock signal in a pre-running interval before transmitting the one or more initial patterns.

19. The operating method of claim 13, further comprising:
generating, by the second device, internal data and an internal inversion flag based on the data and the inversion flag;
capturing, by the second device, the internal data and the internal inversion flag based on the internal clock signal; and
selectively inverting, by the second device, the captured internal data based on the captured internal inversion flag.
